(19) United States
(12) Patent Application Publication
(10) Pub. No.: US 2002/0114204 A1
(43) Pub. Date: Aug. 22, 2002

(54) Power saving semi-conductor integrated circuit

(76) Inventors: Alain Michel Marie Thijs, Eindhoven (NL); Martien Troost, Eindhoven (NL)

Correspondence Address: U.S. Philips Corporation, 580 White Plains Road, Tarrytown, NY, 10591, US

(21) Appl. No.: 10/055,363

(22) Filed: Jan. 23, 2002

(30) Foreign Application Priority Data
Jan. 26, 2001 (EP) 01200304.2

(51) Int. Cl. G11C 5/14

(52) U.S. Cl. 365/227

(57) ABSTRACT

In order to provide a reduction in power wasted by leakage currents in a CMOS SRAM without unduly compromising speed performance or increasing the chance of data errors, the invention proposes a device and method for selectively deactivating peripheral parts of the memory when the memory is in a stand-by mode. The device proposed for implementing the invention comprises a memory made up of cells (10) and peripheral circuits (20), and a transistor switch (30A_{—}30I) capable of interrupting the power supply to the peripheral circuits (20) depending on the voltage supplied to it on a power down (PD) select line and thus reducing the power wasted by leakage currents in the peripheral circuits (20). The transistor switch (30A_{—}30I) cooperates with the peripheral circuits (20) to ensure that data integrity is maintained in a stand-by mode and that a high operating speed is possible when either writing to or reading from the memory cells (10). Preferably, the transistor switch is distributed along the exterior of the peripheral circuits.

The invention relates to a device and method for power management in semiconductor integrated circuits, in particular in memory circuits.

As technology advances, there is a continuing reduction in the minimum feature size definable in semi-conductor production processes. Processes for the production of complementary metal oxide semi-conductor (CMOS) devices are currently available with a minimum feature length of below one micron, and there is continuing progress towards reducing the minimum feature length still further.

The progress towards further miniaturization in CMOS processes is motivated by the higher maximum operation speed possible in such deep sub-micron circuits. Unfortunately, CMOS transistors manufactured to the minimum feature size using such deep sub-micron processes have higher leakage currents in the off state. The magnitude of the off state leakage currents increases rapidly as the size of the transistors decreases.

In hand-held applications where power is provided from a battery the energy wasted by the increased leakage currents is unacceptable. Many hand held applications comprise memory circuits, in particular embedded static random access memory (SRAM). As the leakage current for each transistor in the SRAM increases, the power dissipated by the memory increases substantially. This can cause a dramatic reduction in the battery life of a hand-held application, which is unacceptable. It is therefore desirable to reduce the leakage current in embedded SRAMs while maintaining the advantages of high-speed operation conferred by using very small devices.

One method for reducing the power supply in a circuit comprising numerous CMOS transistors is to use a single transistor switch to interrupt the power supply to the circuit block. Such a technique is described in U.S. Pat. No. 5,274,601. This technique is unsuitable for use with volatile SRAM circuits since the content of the SRAM cells would be lost on power down. Another alternative method is to use transistors with a high threshold voltage V_{T} but this has the disadvantage of decreasing the maximum possible operating speed.

It is an object of embodiments of the present invention to provide a device and method for power management in semi-conductor integrated circuits, in particular in memory circuits, for reducing the leakage current in embedded SRAMs while maintaining the advantages of high speed operation conferred by using very small devices.

According to an aspect of the present invention, there is provided a device for power management in semi-conductor integrated memory circuits, characterized in that the device comprises a transistor switch for interrupting the power supply to circuits peripheral to the memory whilst maintaining the power supply to the memory cells.

According to another aspect of the invention, there is provided a method for power management in semi-conductor integrated memory circuits, the method being characterized by: interruption of the power supply to circuits peripheral to the memory and maintenance of the power supply to the memory cells wherein said interruption is effected by a transistor switch.

Preferably, the transistor switch is comprises a plurality of transistors operated in parallel, or a distributed transistor. This plurality of transistors or this transistor connects a primary power supply conductor and a secondary power supply conductor, to which the power supply from the primary power supply conductor is switched on and off by the transistor switch. The power supply conductors run along the exterior of the peripheral circuits and the plurality of transistors or the distributed transistor is distributed along a substantial extent of the exterior. By “substantial extent” is meant an extent of more than a single row or column of the memory matrix and preferably along all of the rows and/or columns of the memory matrix, lacking not more than a few rows or columns.

The primary power supply conductor acts as a power supply capacitance that stores charge that can supply transient currents before an external current starts running through the power supply. When a current surge is needed locally in the peripheral circuits, the distribution of the switches ensures that current is drawn locally from the primary power supply conductor, avoiding long power supply loops, which could cause delay and ringing.

The primary power supply connection may be connected to the power supply connections of the cells in the memory matrix in a distributed way. Thus, the memory matrix will act as an additional, large power supply capacitance.

Preferably, cells that are connected to certain parts of the periphery have their power supply connected to the primary power supply conductor near to where these certain parts of the periphery have their power supply conductor connected to the secondary power supply conductors (“near” in the sense that the connections are not more than a few (e.g. 1 or 2) row or column spacings of the memory matrix apart). Thus, the distributed transistor switches ensure that power supply current surges due to switching of such a certain part of the periphery remain local. This reduces the transient current demand on the power supply when the SRAM memory cells are switching. Suitably the distributed transistor switch is arranged to minimize the size of the current loops between the switch and the memory cells, thereby reducing the inductance of these loops and maximizing the current available from the power supply capacitance formed by the memory cells.

The device is of particular advantage in a cellular telephone in which power supply requirements are at a premium.

The dimensions of the distributed transistor switch may be determined from a consideration of the size of the memory, the activity of the memory and the required speed of operation. Suitably, generation of the dimensions of the distributed transistor switch for a particular memory device may occur automatically for given values of the parameters listed above.

The distributed transistor switch may be arranged between a power supply line and a virtual power supply line, the virtual power supply line supplying power to the peripheral circuits. Furthermore, the drain-source path of the distributed transistor switch may be connected to the power supply line and the virtual power supply line, the electrical connection between the power supply line and the virtual power supply line depending on the presence or absence of a control voltage at the gate of the distributed transistor switch.

The use of a distributed transistor switch ensures data integrity is maintained in a stand-by mode and provides a high operating speed.

For a better understanding of the invention, and to show how embodiments of the same may be carried into effect, reference will now be made, by way of example, to the accompanying diagrammatic drawings in which:

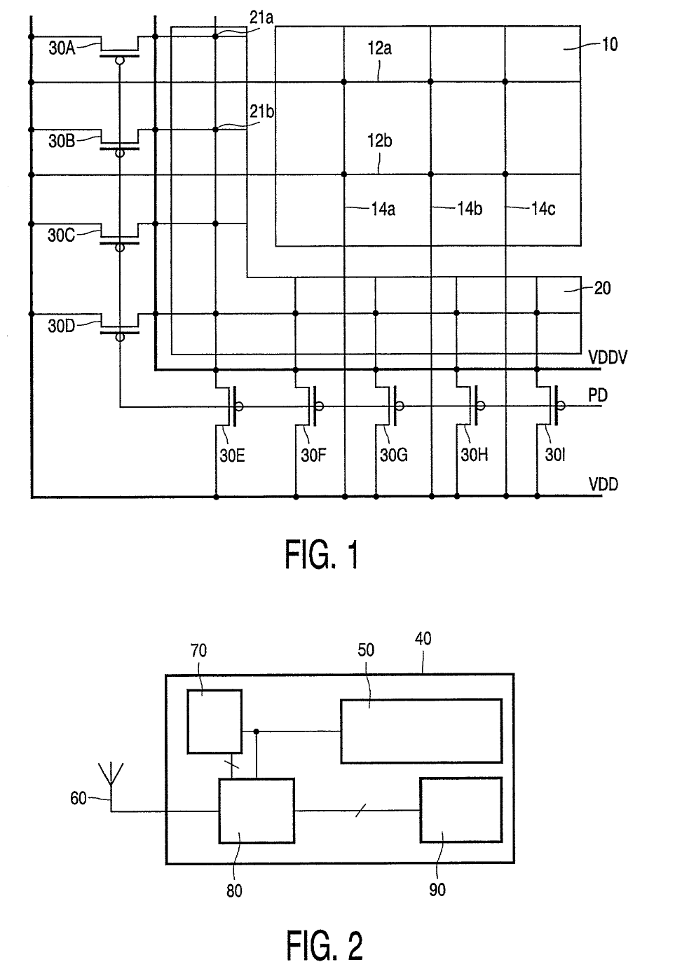

FIG. 1 is a schematic circuit diagram of an embodiment of the present invention.

FIG. 2 is a schematic illustration of a cellular telephone incorporating a device according to the present invention.

Referring now to FIG. 1, there is shown an example of a device embodying the present invention. The device comprises a memory made up of an array of memory cells 10 and a block of circuits 20 peripheral to the memory cells 10, a power supply line VDD, a virtual power supply line VDDV, a power down select line PD and a transistor switch 30 represented by the discrete devices 30A to 30I, connected to the supply lines VDD and VDDI all along the geometrical extent of the block of circuits 20. The transistor switch 30 can be implemented as a distributed transistor, that is, as a transistor with a channel that extends (parallel to its gate) along all connections to the supply line VDD and/or VDDV shown in FIG. 1. The connections between this distributed transistor and the supply lines VDD, VDDV may be local, or they may be continuous, extending along the supply lines. The transistor switch 30 can alternatively be implemented as a set of separate transistors in parallel circuit, as shown in FIG. 1, each possibly extending along part of the block of circuits 20.

The array of memory cells 10 comprises a plurality of memory cells arranged in a matrix. The array of memory cells 10 comprises CMOS SRAM cells (not individually shown) that are permanently electrically connected to power supply line VDD via conductors 12a,b 14a-c. For reasons of clarity, the return power supply line VSS, and the internal details of each memory cell are not shown. In order to further minimize the energy wasted in the memory, the memory cells 10 are ultra low leakage SRAM cells comprising high V_{T} transistors specifically designed to reduce leakage currents without unduly compromising speed performance such as those available under the name KVFSRAM produced on the 0.18 micron CMOS 18 process.

The block of circuits 20 may comprise address and data decoders, sense amplifiers and other circuits. The address decoder, for example, can be used to drive word lines (not shown) to activate all memory cells in a row of the memory matrix. In an embodiment, the address decoder contains a respective driving circuit for each row. Each driving circuit has a separate power supply connection 21a-b connected to the virtual power supply line VDDV, so that the connections of these power supply connections to the virtual power supply line are distributed over the virtual power supply line VDDV. The sense amplifiers, for example, can be used to amplify data received via bit lines (not shown) from cells in the activated row. Each sense amplifier has a power supply connection to the virtual power supply line VDDV, so that the connections of these power supply connections to the virtual power supply line are distributed over the virtual power supply line. The other circuits may include precharge circuits, each for precharging a respective bit line, each precharge circuit having a power supply connection connected to the virtual power supply line VDDV, so that the connections of these power supply connections to the virtual power supply line are distributed over the virtual power supply line.

Preferably, the power supply connection of a cell of the memory is connected via conductors 12a-b, 14a-c to the power supply connection VDD near to the location (or locations) where the part of the peripheral circuits 30 that is involved with that cell is connected to the virtual power supply connection VDDV. For example, the power supply of a row of cells will be connected near to where the address decoder for that row is connected and the power supply for a column of cells is connected near to where the sense amplifiers or precharge circuits for that column are connected (crossed connections for rows and columns may be used). This allows current surges for local peripheral circuits to be drawn mainly from the power supply capacitance formed by the cells involved with these local circuits. This reduces the length of power supply loops.

If ultra low leakage SRAM cells are used in the array of memory cells 10 then the circuits providing block 20 may be optimized to cooperate with such memory cells, in particular the sense amplifiers may operate in a current sense mode to reduce their response time. The block of circuits 20 is not directly connected to the power supply line VDD. The power supply line VDD is connected to the virtual power supply line VDDV though the drain-source conduction path of the distributed transistor switch 30. The distributed transistor switch 30 comprises a PMOS transistor, the gate of which is connected to the power down select line PD. The distributed transistor switch 30 is a power switch off transistor.

When the array of memory cells 10 is being read from or written to under the control of the circuits of block 20 the power down select line is held at a low voltage and the distributed transistor switch 30 is fully conducting. Power is thus supplied to both the block of circuits 20 and the array of memory cells 10. To conserve power when data is neither being read from nor written to the array of memory cells 10 the power down select line PD is made high and therefore the distributed transistor switch 30 switches off to become non-conducting. Any residual charge in the block of circuits 20 decays away so that all circuits therein assume a logic state 0. The block of circuits 20 is designed so that attempts to read from or write to memory cells 10 are initiated by control lines assuming a logic 1 level. The power to the array of memory cells 10 supplied from VDD is maintained so that none of the data stored in the memory cells 10 is lost. Since no power is being supplied to the block of circuits 20 no spurious commands to either read from or write to the memory cells 10 can be generated as these require the presence of a logic 1. The block of circuits 20 is also designed to ensure that no hang-ups exist and to produce proper memory control signals when switched on. This ensures that the memory is correctly written to or read from after a period of time spent in the stand-by state.

It will be appreciated by the person skilled in the art that although a specific SRAM circuit layout has been shown, equivalent circuitry may replace the elements shown in FIG. 1. For instance, logic families other than CMOS could be used and the arrangement of the transistor switch 30, circuits 20 and memory cells 10 may be different to that shown whilst still achieving the same technical effect.

The circuit of FIG. 1 is usually embedded in a larger circuit implemented on a semi-conductor substrate, such as a larger circuit for telephony that also contains for example a processor, interface circuitry etc. During the design of such a larger circuit, the layout of memory matrix 10 is preferably generated automatically with a computer program (called a memory generator), as a function of a specification of the size and dimensions of the memory matrix as required in the larger circuit. The layout is subsequently implemented in masks that are used to manufacture the device.

The memory generator generates a layout description for the matrix 10, the periphery 20, the power supply lines VDD, VDDI and the switch 30. The memory scales the switch with the specified memory size, so that it extends substantially along the entire periphery 20, or one functional part of the periphery, such as the address decoder. This extension may be realized by generating the layout of a distributed transistor extending along the periphery or by generating the layout of a number of separate transistors in parallel circuit. By generating a distributed transistor with an extent proportional to the size of the memory, or a number of transistors proportional to the size of the memory, the program generator also adapts the driving strength of the switch 30 to the specified size of the memory. Thus it is ensured that driving strength is available in proportion to the size of the periphery and the memory circuit, so that the switch 30 does not become too large or to small, dependent on whether the memory is small or large respectively. This simplifies the design of the computer program that implements the memory generator.

FIG. 2 shows a cellular telephone 40 comprising a battery 50, an aerial 60, a user interfacing block 70, a microprocessor 80 and a memory chip 90 according to the present invention. The microprocessor 80 controls the operation of the cellular telephone 40 according to signals received from the aerial 60 and the user-interfacing block 70. The microprocessor 80 can read from or write to the memory chip 90, which is isolated from the power supply according to the present invention when neither of these operations is being carried out. In other applications of memory according to the present invention within cellular telephones, the memory may be incorporated in a single chip with the microprocessors for controlling the operation of the telephone.

As described above, power saving devices and methods according to preferred embodiments of the present invention confer advantages over the state of the art in maintaining high speed operation of SRAMs manufactured using a deep sub micron CMOS process while reducing power wastage through leakage currents. It is anticipated that a reduction in leakage currents by up to a factor of 300 can be achieved without compromising speed performance by more than 10%. These factors will depend on the number of memory cells in relation to the size of the peripheral circuits and on the amount of time the memory spends in a stand-by state.

The reader's attention is directed to all papers and documents which are filed concurrently with or previous to this specification in connection with this application and which are open to public inspection with this specification, and the contents of all such papers and documents are incorporated herein by reference.

All of the features disclosed in this specification (including any accompanying claims, abstract and drawings), and/or all of the steps of any method or process so disclosed, may be combined in any combination, except combinations where at least some of such features and/or steps are mutually exclusive.

Each feature disclosed in this specification (including any accompanying claims, abstract and drawings), may be replaced by alternative features serving the same, equivalent or similar purpose, unless expressly stated otherwise. Thus, unless expressly stated otherwise, each feature disclosed is one example only of a generic series of equivalent or similar features.

The invention is not restricted to the details of the foregoing embodiment(s). The invention extend to any novel one, or any novel combination, of the features disclosed in this specification (including any accompanying claims, abstract and drawings), or to any novel one, or any novel combination, of the steps of any method or process so disclosed.

1. A device containing a semi-conductor integrated memory circuit and a circuit for power management, characterized in that the circuit for power management comprises a transistor switch for interrupting the power supply to circuits peripheral to the memory whilst maintaining the power supply to cells of the memory.

2. A device according to claim 1, the memory and the circuits peripheral to the memory occupying a region in a semi-conductor substrate, the circuit for power management containing a primary and a secondary power supply conductor running along at least part of an exterior of said region, the primary power supply conductor being coupled to the power supply, the secondary power supply conductor being coupled to supply inputs of the circuits peripheral to the memory, the transistor switch comprising a distributed transistor between the primary secondary power supply conductor, and/or a plurality of transistor switches connected in parallel between the primary secondary power supply conductor, extending distributed along a substantial part of the exterior.

3. A device according to claim 1, the cells of the memory having power supply connections connected to the primary power supply conductor distributed along the exterior.

4. A device according to claim 2, in which the circuits peripheral to the memory comprise address decoder circuits, each arranged to drive a different word line, the address decoders having power supply inputs coupled in parallel to the secondary power supply conductor.

5. A device according to claim 2, in which the circuits peripheral to the memory comprise bit line precharge circuits each arranged to precharge a different bit line, the bit-line precharge circuits having power supply inputs coupled in parallel to the secondary power supply conductor.

6. A device according to claim 1, in which the memory cells comprise ultra low leakage cells.

7. A device according to claim 1, the circuits peripheral to the memory comprising sense amplifiers configured to operate in a current sense mode.

8. A method for power management in semi-conductor integrated memory circuits, the method being characterized by: interruption of the power supply to circuits peripheral to the memory and maintenance of the power supply to the memory cells wherein said interruption is effected by a transistor switch.

9. A method according to claim 7, wherein the transistor switch comprises a distributed transistor, or a plurality of transistors, distributed along a substantial part of an exterior of the circuits peripheral to the memory.

10. A method according to claim 8, in which the distributed transistor switch extends substantially all along the circuits peripheral to the memory cells.

11. A device according to claim 1, in which the device is in a cellular telephone.

12. A method of manufacturing a device with a memory, the method comprising specifying a memory size and running a computer program that generates
a layout of a circuit with a memory of the specified size,
circuits peripheral to the memory and
a circuit for power management that comprises a first number of transistor switches connected in parallel, or a distributed transistor with a lateral extent, for interrupting the power supply to the circuits peripheral to the memory whilst maintaining the power supply to the memory cells, said first number or said lateral extent being selected in proportion to the specified size.
